(19) United States
(12) Patent Application Publication
(10) Pub. No.: US 2025/0300129 A1
(43) Pub. Date: Sep. 25, 2025

(54) INTEGRATED CIRCUIT PACKAGES INCLUDING MULTI-DIE STACKS HAVING TAPERED SIDEWALLS

(71) Applicant: Intel Corporation, Santa Clara, CA (US)

(72) Inventors: Jeffery D. Bielefeld, Forest Grove, OR (US); Adel A. Elsherbini, Chandler, AZ (US); Kimin Jun, Portland, OR (US); Golsa Naderi, Portland, OR (US); Tushar Talukdar, Wilsonville, OR (US); Manuel Tolentino Pena, Chandler, AZ (US); Shawna M. Liff, Scottsdale, AZ (US); Sairam Agraharam, Chandler, AZ (US); Feras Eid, Chandler, AZ (US); Jiraporn Seangatith, Chandler, AZ (US)

(73) Assignee: Intel Corporation, Santa Clara, CA (US)

(21) Appl. No.: 18/615,041

(22) Filed: Mar. 25, 2024

(51) Int. Cl. H01L 25/065; H01L 23/00; H01L 23/29; H01L 23/31

(52) U.S. Cl. CPC H01L 25/0652; H01L 23/3185; H01L 23/291; H01L 24/08; H01L 2224/08145; H01L 2224/08225

(57) ABSTRACT

Microelectronic assemblies, related devices and methods, are disclosed herein. In some embodiments, a microelectronic assembly may include a die; a first multi-die stack coupled to the die, wherein the first multi-die stack includes a plurality of dies having a first tapered profile with an internal angle between 77 degrees and 87 degrees; and a second multi-die stack coupled to the die adjacent to the first multi-die stack, wherein the second multi-die stack includes a plurality of dies having a second tapered profile with an internal angle between 77 degrees and 87 degrees, and wherein the first tapered profile and the second tapered profile form a space between the first multi-die stack and the second multi-die stack that narrows towards the die.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic cross-sectional view of an example microelectronic assembly according to some embodiments of the present disclosure.

FIG. 1B is a schematic cross-sectional view of a portion of the example microelectronic assembly of FIG. 1A.

FIG. 1C is a schematic cross-sectional view of the example multi-die stack of FIG. 1A according to some embodiments of the present disclosure.

FIG. 1D is a top view of the example multi-die stack of FIG. 1C according to some embodiments of the present disclosure.

FIG. 2A is a schematic cross-sectional view of another example microelectronic assembly according to some embodiments of the present disclosure.

FIG. 2B is a schematic cross-sectional view of the example multi-die stack of FIG. 2A according to some embodiments of the present disclosure.

FIG. 3A is a schematic cross-sectional view of yet another example microelectronic assembly according to some embodiments of the present disclosure.

FIG. 3B is a schematic cross-sectional view of the example multi-die stack of FIG. 3A according to some embodiments of the present disclosure.

FIGS. 4A-4C are schematic cross-sectional views of different stages of an example process for manufacturing the tapered dies of FIG. 2A according to some embodiments of the present disclosure.

FIGS. 5A-5C are schematic cross-sectional views of different stages of an example process for manufacturing the tapered dies of FIG. 1A according to some embodiments of the present disclosure.

FIGS. 6A-6D are schematic cross-sectional views of different stages of an example process for manufacturing microelectronic assembly of FIG. 1A according to some embodiments of the present disclosure.

FIG. 7 is a schematic top view of an example arrangement of multi-die stacks in a microelectronic assembly according to some embodiments of the present disclosure.

FIG. 8 is a cross-sectional view of a device package that includes one or more microelectronic assemblies in accordance with any of the embodiments disclosed herein.

FIG. 9 is a cross-sectional side view of a device assembly that includes one or more microelectronic assemblies in accordance with any of the embodiments disclosed herein.

FIG. 10 is a block diagram of an example computing device that includes one or more microelectronic assemblies in accordance with any of the embodiments disclosed herein.

### DETAILED DESCRIPTION

For purposes of illustrating IC packages described herein, it is important to understand phenomena that may come into play during assembly and packaging of ICs. The following foundational information may be viewed as a basis from which the present disclosure may be properly explained.

Such information is offered for purposes of explanation only and, accordingly, should not be construed in any way to limit the broad scope of the present disclosure and its potential applications.

As demands for high performance computing (HPC) continue to rise, heterogeneous integration has become an important performance enabler. The focus to enable heterogeneous integration scaling is to push interconnect density with increased bandwidth and improved power efficiency. Many different advanced packaging architectures have been deployed to increase planar and 3-dimensional (3D) input/output (I/O) wire per area density for higher data bandwidth requirements, and to enable more effective die disaggregation and heterogeneous integration to shorten the time to market. More recently, industry has moved quickly into 2.5D/3D advanced packaging technologies, such as die embedding and/or silicon interposer to enable significantly higher package I/O counts and density to meet the HPC segment market demands and product performance needs.

At the same time, system level heterogeneous integration has been attracting significant interest due to its extremely high potential in supercomputing, autonomous driving, and machine learning applications. Extremely high-performance computing drives significant packaging innovations and disruptive system level architectures. Such high performance computing demand drives very large form factor package and system level heterogenous integration of compute tiles, I/O, memory, power delivery, and thermal cooling solutions. The microelectronic assemblies disclosed herein may achieve very large form factor structures having increased interconnect densities, reduced routing distances, and improved signal and power integrity compared to conventional approaches, without costly manufacturing operations. Further, the microelectronic structures and assemblies disclosed herein offer new flexibility to electronics designers and manufacturers, allowing them to select an architecture that achieves their device goals without excess cost or manufacturing complexity.

One stacking method may comprise electrically coupling relatively small dies to a relatively large die. The large die also may be referred to herein as a “base die.” In one example, the large die may be configured to be attached to an electronic substrate or board and the small dies may be on top of the larger die. In some cases, the small dies may be stacked. The spaces between the small dies are typically filled with a dielectric material (e.g., an oxide material, such as silicon dioxide), which provides mechanical stability for further die stacking and enables patterning of conductive pathways, such as conductive vias called through-dielectric vias (TDV), between the small dies. The small dies generally have a cuboidal or rectangular prism shape with 90-degree angles at all corners. The dielectric material is usually deposited on a top surface and on side surfaces of the small dies, and then the dielectric material grows to fill the space between the small dies. The dielectric material has some limitations in filling these sharp 90-degree angles during the deposition process that results in the formation of voids and pinch offs, and/or results in large amounts of material being deposited and subsequently removed (e.g., overburden material). Voids may decrease functionality, increase shorting, and adversely impact metallization fill and conductive pathway patterning. Typically, a dielectric material has an overburden thickness equal to a thickness of the small die, so a substantial amount of dielectric material is wasted. For example, for a small die thickness of 20 microns, 40 microns, and 80 microns, a dielectric material deposition thickness of 27 microns, 47 microns, and 87 microns, respectively, is required (e.g., a thickness of at least 7 microns of overburden is required). Structures and methods that prevent void formation and minimize the amount of overburden of dielectric material required to completely fill the spaces between the small dies may be desired.

Disclosed herein are microelectronic assemblies with structures for improved and minimized dielectric deposition, where the small dies have tapered sidewalls to form spaces having angles that are greater than 90 degrees, where the small dies are stacked to have an angled profile and the dielectric material is deposited in the spaces subsequent to die stacking, and where the small dies are arranged in a staggered layout pattern to minimize the amount of dielectric material that needs to be deposited to fill the spaces. These microelectronic assemblies reduce the amount of dielectric material being deposited, reduce the formation of voids, reduce the amount of overburden material needing to be removed (e.g., planarized), and reduces an overall cost of manufacturing in terms of material cost and the number of manufacturing steps required. Further, these microelectronic assemblies with structures for improved and minimized dielectric deposition may allow for reduced spacing between the small dies allowing for more small dies to be electrically coupled to a base die or allowing for a smaller base die.

Accordingly, microelectronic assemblies, related structures and methods, are disclosed herein. In some embodiments, a microelectronic assembly may include a die; a first multi-die stack coupled to the die, wherein the first multi-die stack includes a plurality of dies having a first tapered profile with an internal angle between 77 degrees and 87 degrees; and a second multi-die stack coupled to the die adjacent to the first multi-die stack, wherein the second multi-die stack includes a plurality of dies having a second tapered profile with an internal angle between 77 degrees and 87 degrees, and wherein the first tapered profile and the second tapered profile form a space between the first multi-die stack and the second multi-die stack that narrows towards the die.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. A dielectric material may include any suitable dielectric material commonly used in semiconductor manufacture, such as silicon and one or more of oxygen, nitrogen, hydrogen, and carbon (e.g., in the form of silicon oxide, silicon nitride, silicon oxynitride, or silicon carbon nitride); a polyimide material; or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other.

However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure. In some embodiments, DTD interconnects may be hybrid bonds including metal-metal bonds and dielectric-dielectric bonds. In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

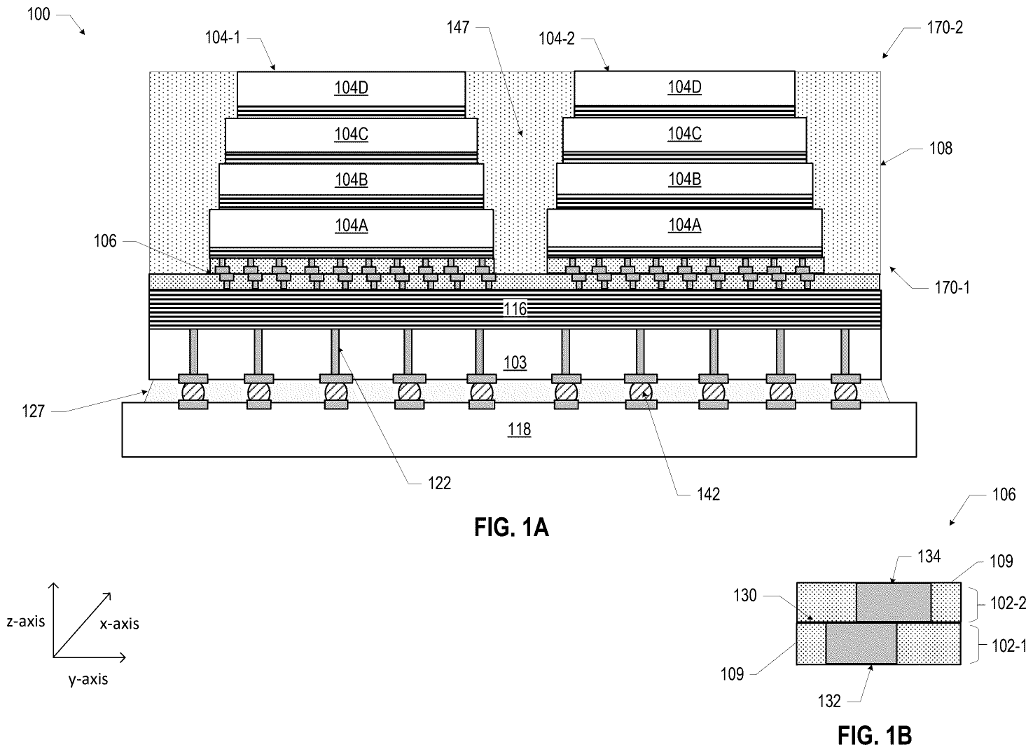

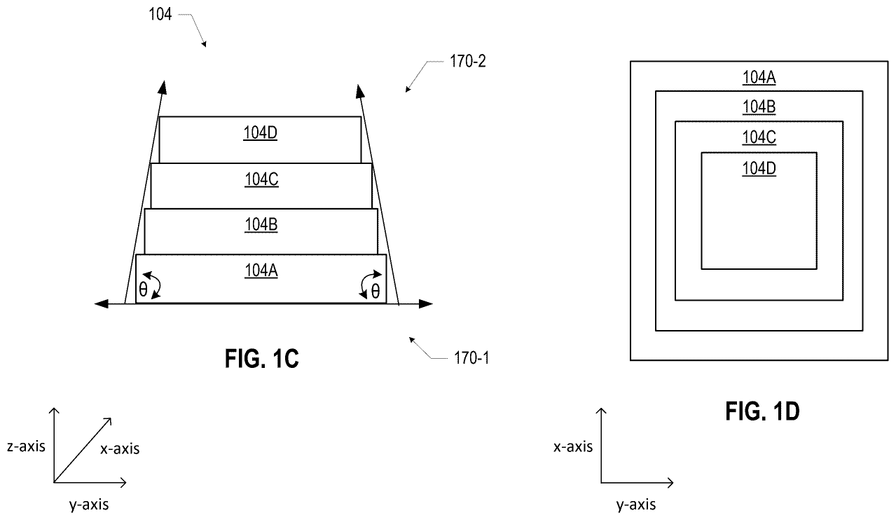

For convenience, if a collection of drawings designated with different letters are present (e.g., FIGS. 1A and 1B), such a collection may be referred to herein without the letters (e.g., as “FIG. 1”). Similarly, if a collection of reference numerals designated with different numerals or letters are present (e.g., 104-1, 104-2), such a collection may be referred to herein without the numerals or letters (e.g., as “104”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

FIG. 1A is a schematic cross-sectional view of an example microelectronic assembly 100 according to some embodiments of the present disclosure. Microelectronic assembly 100 a first muti-die stack 104-1 and a second multi-die stack 104-2 electrically coupled to a base die 103 by interconnects 106, where the first muti-die stack 104-1 and the second multi-die stack 104-2 have a tapered profile. The second muti-die stack 104-2 is adjacent to the first multi-die stack 104-1 and forms a space 147 with a tapered profile between the first muti-die stack 104-1 and the second multi-die stack 104-2 that narrows towards the base die 103. The first muti-die stack 104-1 and the second multi-die stack 104-2 include a plurality of dies 104 (e.g., 104A, 104B, 104C, 104D) coupled to adjacent dies 104 by interconnects 106 (not shown).

FIG. 1B is a schematic cross-sectional view of a detail of a particular one of interconnects 106 in microelectronic assembly 100. An example of interconnect 106 in some embodiments is a hybrid bond, comprising metal-metal and dielectric-dielectric bonds. Note that although only interconnect 106 is shown, the same structure and description may apply to any other such interconnects comprising hybrid bonds in microelectronic assembly 100 where applicable. In a general sense, interconnect 106 may include, at an interface 130 between layers 102-1 and 102-2, metal-metal bonds between bond-pad 132 of layer 102-1 and bond-pad 134 of layer 102-2, and dielectric-dielectric bonds (e.g., oxide-oxide bonds) in a dielectric material 109 of layers 102-1 and 102-2. Bond-pad 132 of layer 102-1 may bond with bond-pad 134 of layer 102-2. Dielectric material 109 (e.g., silicon oxide, silicon nitride, silicon oxynitride, etc.) in layers 102-1 and 102-2 may bond with each other. In some embodiments, the dielectric material 109 may be a same material as the dielectric material 108. The bonded metal and dielectric materials form interconnect 106, comprising hybrid bonds, providing electrical and mechanical coupling between layers 102-1 and 102-2. In various embodiments, interconnects 106 may have a linear dimension of less than 5 micrometers and a pitch of less than 10 micrometers between adjacent interconnects.

FIG. 1C is a schematic cross-sectional view of an example multi-die stack according to some embodiments of the present disclosure. A multi-die stack 104 may include a plurality of stacked dies 104A, 104B, 104C, 104D having decreasing surface areas (e.g., xy-dimension) towards a top 170-2 of the multi-die stack 104 forming a first tapered profile with an internal angle between 77 degrees and 87 degrees (e.g., increasing surface areas towards a bottom 170-2 of the multi-die stack 104). The dies 104A, 104B, 104C, 104D may have a cuboidal or a rectangular prism shape with 90-degree angles at each corner.

FIG. 1D is a top view of the example multi-die stack of FIG. 1C showing decreasing surface areas (e.g., xy-dimension) towards a top of the multi-die stack 104 (e.g., die 104A has a largest surface area and die 104D has a smallest surface area). The decreasing surface areas may define the tapered profile having an internal angle between 77 degrees and 87 degrees.

Although FIG. 1 illustrates a multi-die stack 104 having four dies (e.g., die 104A, 104B, 104C, 104D), a multi-die stack 104 may have any suitable number of dies, including between two and four. A multi-die stack 104 may have any suitable dimensions. For example, a multi-die stack 104 may have a thickness (e.g., z-height) between 100 microns and 200 microns.

Returning to FIG. 1A, the microelectronic assembly 100 may further include a dielectric material 108 surrounding the first muti-die stack 104-1 and the second multi-die stack 104-2 and in the space 147 between the first muti-die stack 104-1 and the second multi-die stack 104-2. A dielectric material 108 may include an inorganic material, for example, silicon and oxygen (e.g., in the form of silicon oxide), or silicon and oxygen and one or more of nitrogen and carbon (e.g., in the form of silicon oxynitride, silicon oxycarbide, or silicon oxycarbonitride), and/or other forms of inorganic dielectric material typically used as interlayer dielectric (ILD) in semiconductor devices. The dielectric material 108 may be deposited using any suitable technique, such as chemical vapor deposition, physical vapor deposition, plasma enhanced chemical vapor deposition, among others. The dielectric material 108 may be deposited on a top 172-2 and on side surfaces of the multi-die stacks 104 to fill the space 147. A space 147 between the first multi-die stack and the second multi-die stack may have an aspect ratio equal to or greater than 0.4. An aspect ratio of a space 147 may be determined based on an overall thickness (e.g., z-height) to a narrowest gap width (e.g., y-dimension between die 104A of the first muti-die stack 104-1 and die 104A of the second multi-die stack 104-2). A dielectric material 108 that covers a top 172-2 of the multi-die stacks 104 (e.g., an overburden material) may be removed using any suitable technique, including grinding or chemical mechanical polishing (CMP). The amount of overburden dielectric material to be removed may be minimized due to the tapered profile of the multi-die stacks 104. In some embodiments, the multi-die stack 104 may be pre-assembled, electrically coupled to the base die 103, and the dielectric material 108 may be deposited on the multi-die stacks 104. In some embodiments, the dielectric material 108 may be deposited at each layer of the multi-die stack 104. For example, die 104A of the multi-die stacks 104 may be electrically coupled to the base die 103, and the dielectric material 108 may be deposited on the die 104A and the overburden may be removed, then the next die 104B may be electrically coupled to the die 104A and the dielectric material 108 may be deposited on the die 104B and the overburden may be removed, and so on.

A base die 103 may be referred to as an “interposer,” a “wafer,” or a “die.” The base die 103 may include an insulating material (e.g., one or more dielectric materials formed in multiple layers, as known in the art) and one or more conductive pathways through the insulating material (e.g., including conductive lines and/or conductive vias). Conductive pathways may be present in a metallization stack 116 having a plurality of metal layers through insulator fabricated using known semiconductor manufacturing processes. In some embodiments, the insulating material of the base die 103 includes an inorganic dielectric material, such as silicon and nitrogen (e.g., in the form of silicon nitride); silicon and oxygen (e.g., in the form of silicon oxide); silicon and carbon (e.g., in the form of silicon carbide); silicon, carbon, and oxygen (e.g., in the form of silicon oxycarbide); silicon, carbon, and nitrogen (e.g., in the form of silicon carbonitride); carbon and oxygen (e.g., in the form of a carbon-doped oxide); silicon, oxygen, and nitrogen (e.g., in the form of silicon oxynitride); or silicon, oxygen, carbon, and hydrogen (e.g., in the form of tetraethyl orthosilicate (TEOS)); and combinations thereof. In some embodiments, the insulating material of the base die 103 includes an insulating metal oxide, such as aluminum and oxygen (e.g., in the form of aluminum oxide); titanium and oxygen (e.g., in the form of titanium oxide); hafnium and oxygen (e.g., in the form of hafnium oxide); zirconium and oxygen (e.g., in the form of zirconium oxide); niobium and oxygen (e.g., in the form of niobium oxide); or tantalum and oxygen (e.g., in the form of tantalum oxide); and combinations thereof. In some embodiments, the base die 103 may be semiconductor-based (e.g., silicon-based) or glass-based. In some embodiments, the base die 103 is a silicon wafer or die. In some embodiments, the base die 103 may be a silicon-on-insulator (SOI) and may further include layers of silicon and germanium (e.g., in the form of silicon germanium), gallium and nitrogen (e.g., in the form of gallium nitride), indium and phosphorous (e.g., in the form of indium phosphide), among others. In some embodiments (as shown), the base die 103 may include through-substrate vias (TSVs) 122. TSVs 122 may be configured to carry power, signals and/or ground connection between package substrate 118 and the multi-die stacks 104-1, 104-2.

In some embodiments, the plurality of die 104A, 104B, 104C, 104D in the multi-die stacks 104-1, 104-2 may include different kinds of conductive traces, such as conductive traces configured to carry power and conductive traces configured to carry signals, having different dimensions (e.g., conductive traces configured to carry power may, in general, be larger (e.g., thicker, wider) than conductive traces configured to carry signals). Conductive traces may be present in a metallization stack 116 having a plurality of metal layers through insulator fabricated using known semiconductor manufacturing processes. In some embodiments, the insulator material in the metallization stacks may be the same as that of the dielectric material 108 around the multi-die stacks 104-1, 104-2; in other embodiments, the insulator material in the metallization stacks may be different from that of dielectric material 108. In some embodiments, the die 104A, 104B, 104C, 104D may include TSVs (not shown) similar to TSVs 122 of base die 103.

As shown in FIG. 1A, the metallization stack 116 of the base die 103 and the metallization stack 116 of the bottom die 104A of the multi-die stacks 104-1, 104-2 are face-to-face. In other embodiments, the metallization stack 116 of the base die 103 and the metallization stack 116 of the bottom die 104A of the multi-die stacks 104-1, 104-2 are face-to-back (not shown) (e.g., the metallization stack 116 of base die 103 may face away from the metallization stack 116 of the bottom die 104A).

A microelectronic assembly 100 may further include a package substrate 118 having conductive pathways (not shown) through an organic dielectric material. The conductive pathways may include conductive traces coupled by conductive vias. The package substrate 118 may further include bond-pads, redistribution layers, substrate cores, passive components and other elements, which are not shown merely for ease of illustration and not as limitations. Package substrate 118 may be coupled to the base die 103 by interconnects 142 (e.g., DTPS interconnects, such as flip-chip solder bonds). In various embodiments, interconnects 142 may have a pitch greater than 10 micrometers between adjacent interconnects. In some embodiments, interconnects 142 may include solder, as shown. An underfill material 127 may be disposed around interconnects 142. The underfill process may include dispensing underfill material in liquid form, allowing the material to flow and fill interstitial gaps around interconnects 142, and subjecting the assembly to a curing process, such as baking, to solidify the material.

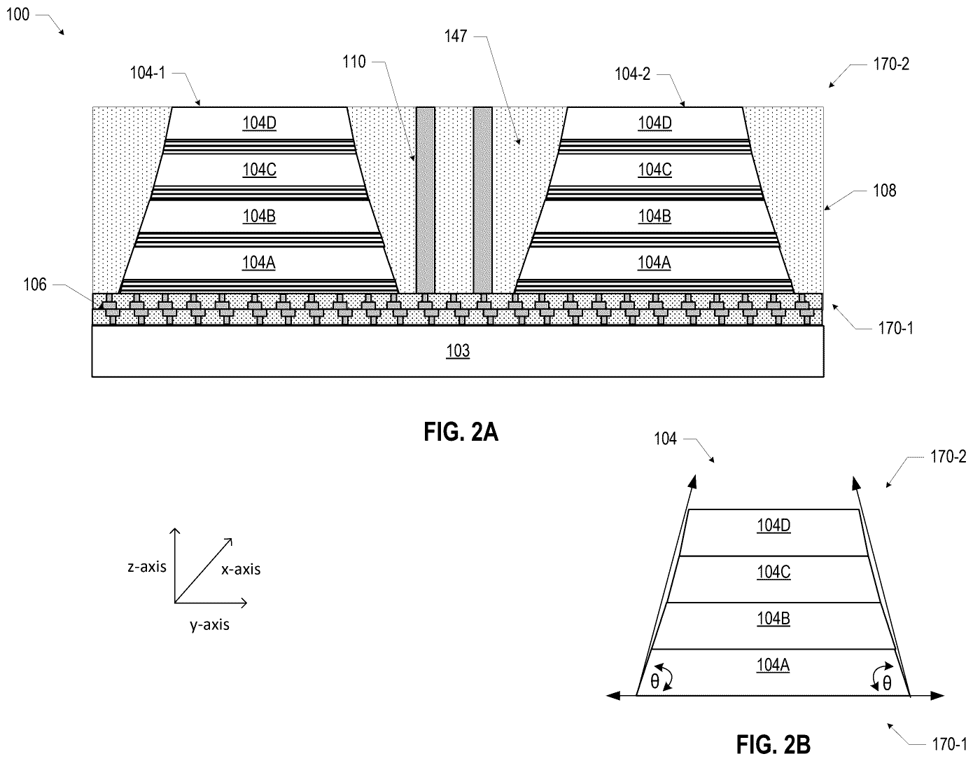

FIG. 2A is a schematic cross-sectional view of another example microelectronic assembly according to some embodiments of the present disclosure. The configuration of the embodiment shown in the figure is like that of FIG. 1A, except for differences as described further. The configuration of the of the microelectronic assembly 100 as described herein includes a first muti-die stack 104-1 and a second multi-die stack 104-2 electrically coupled to a base die 103 by interconnects 106, where the first muti-die stack 104-1 and the second multi-die stack 104-2 have a tapered profile. The second muti-die stack 104-2 is adjacent to the first multi-die stack 104-1 on the base die 103 and forms a space 147 with a tapered profile between the first muti-die stack 104-1 and the second multi-die stack 104-2 that narrows towards the base die 103. The microelectronic assembly 100 further includes a through-dielectric via (TGV) 110 extending through the dielectric material 108 in the space 147 between the first muti-die stack 104-1 and the second multi-die stack 104-2.

FIG. 2B is a schematic cross-sectional view of the example multi-die stack of FIG. 2A according to some embodiments of the present disclosure. A multi-die stack 104 may include a plurality of stacked dies 104A, 104B, 104C, 104D having angled sidewalls that widen from a top 170-2 of the multi-die stack 104 (e.g., die 104D) towards a bottom 170-1 of the multi-die stack 104 (e.g., die 104A) forming a first tapered profile with an internal angle between 77 degrees and 87 degrees. The taper angle of die 104A, 104B, 104C, 104D may be performed using any suitable technique, such as a dicing mask process. Although FIG. 2 illustrates a multi-die stack 104 having four dies (e.g., die 104A, 104B, 104C, 104D), a multi-die stack 104 may have any suitable number of dies, including between two and four. A multi-die stack 104 may have any suitable dimensions, for example, as described above with reference to FIG. 1.

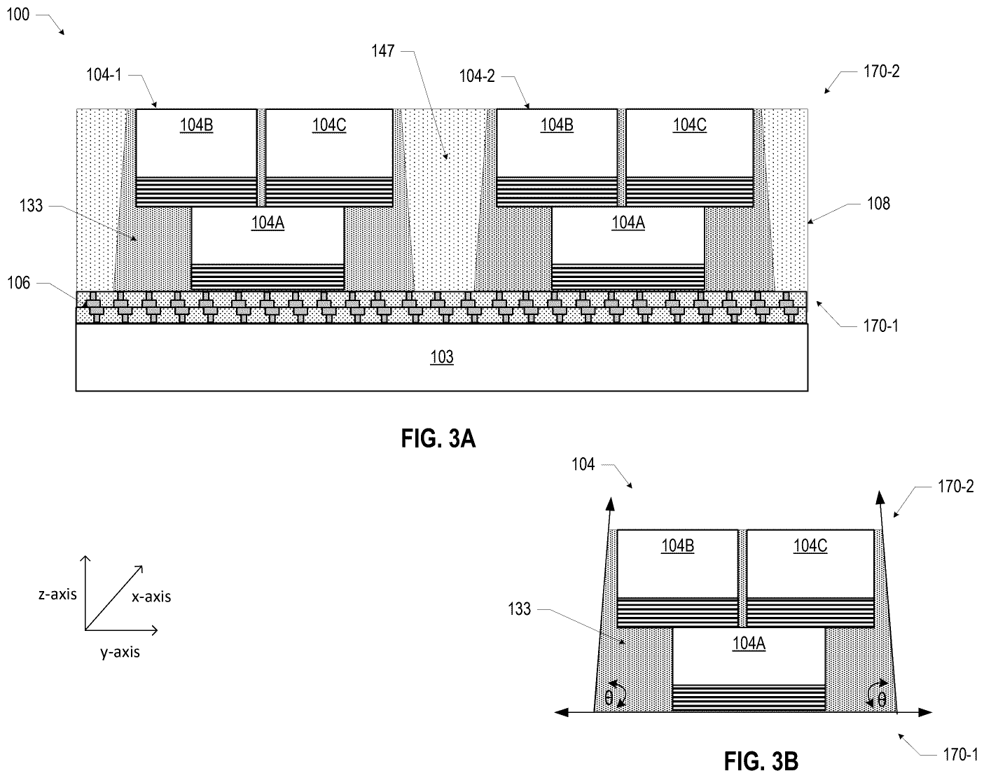

FIG. 3A is a schematic cross-sectional view of yet another example microelectronic assembly according to some embodiments of the present disclosure. The configuration of the embodiment shown in the figure is like that of FIG. 1A, except for differences as described further. The configuration of the of the microelectronic assembly 100 as described herein includes a first muti-die stack 104-1 and a second multi-die stack 104-2 electrically coupled to a base die 103 by interconnects 106, where the first muti-die stack 104-1 and the second multi-die stack 104-2 are surrounded by an insulating material 133 having a tapered profile. The second muti-die stack 104-2 is adjacent to the first multi-die stack 104-1 on the base die 103 and forms a space 147 with a tapered profile between the first muti-die stack 104-1 and the second multi-die stack 104-2 that narrows towards the base die 103. In some embodiments, the insulating material 133 may include a mold material, such as an organic polymer with inorganic silicon oxide, a resin material, or an epoxy material. In some embodiments, the insulating material 133 may include a mold material, a resin material, or an epoxy material, and may further include a thermally conductive material (e.g., metal particles), such as silver and oxygen (e.g., in the form of silver oxide particles) or aluminum and oxygen (e.g., in the form of aluminum oxide particles), or combinations thereof. The tapered profile of the insulating material 133 may be formed using any suitable technique, including a bevel sawing process.

FIG. 3B is a schematic cross-sectional view of the example multi-die stack of FIG. 3A according to some embodiments of the present disclosure. A multi-die stack 104 may include a plurality of stacked dies (e.g., 104A, 104B, 104C) surrounded by an insulating material 133 having angled sidewalls that widen from a top 170-2 of the multi-die stack 104 (e.g., die 104B, 104C) towards a bottom 170-1 of the multi-die stack 104 (e.g., die 104A) forming a first tapered profile with an internal angle between 77 degrees and 87 degrees. The dies 104A, 104B, 104C may have a cuboidal or a rectangular prism shape with 90-degree angles at each corner. Although FIG. 3 illustrates a multi-die stack 104 having three dies (e.g., die 104A, 104B, 104C), a multi-die stack 104 may have any suitable number of dies, including between two and four. A multi-die stack 104 may have any suitable dimensions, for example, as described above with reference to FIG. 1.

Any suitable techniques may be used to manufacture the microelectronic assemblies 100 disclosed herein. Although the operations discussed below are illustrated in a particular order, these operations may be performed in any suitable order. Further, additional operations which are not illustrated may also be performed without departing from the scope of the present disclosure. Also, various ones of the operations discussed herein may be modified in accordance with the present disclosure to fabricate others of microelectronic assembly 100 disclosed herein.

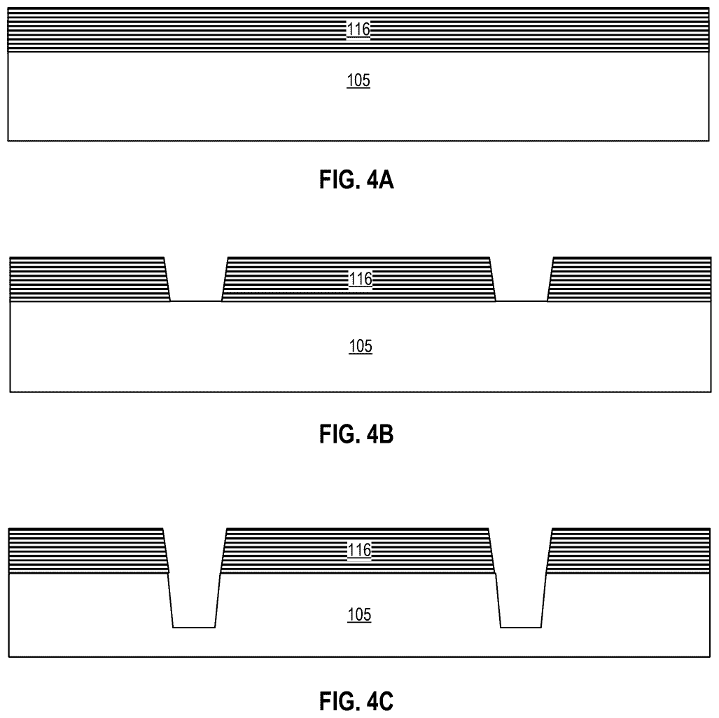

FIGS. 4A-4C are schematic cross-sectional views of different stages of an example process for manufacturing the tapered dies of FIG. 2A according to some embodiments of the present disclosure. FIG. 4A illustrates a wafer substrate 105 having a metallization stack 116 at a top surface (e.g., facing up). FIG. 4B illustrates the assembly of FIG. 4A subsequent to performing an etching process from the top surface of the metallization stack to create tapered sidewalls in the metallization stack 116. The etching process may include any suitable etching process. In some embodiments, a saw dicing process may be used. FIG. 4C illustrates the assembly of FIG. 4B subsequent to performing an etching process from the top surface of the metallization stack 116 to create tapered sidewalls in the wafer substrate 105. The etching process may include any suitable etching process. In some embodiments, a saw dicing process may be used. The assembly of FIG. 4C may undergo further processing, such as singulation.

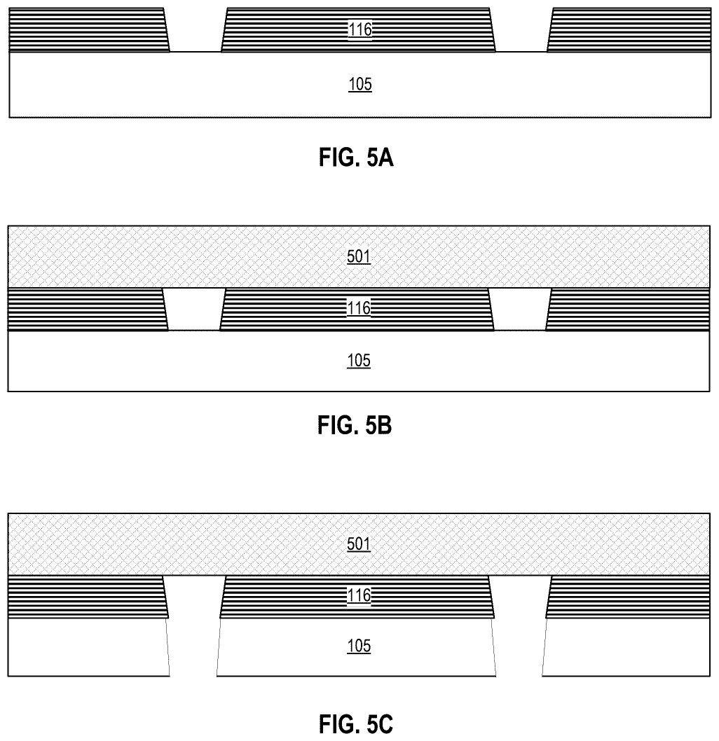

FIGS. 5A-5C are schematic cross-sectional views of different stages of an example process for manufacturing the tapered dies of FIG. 2A according to some embodiments of the present disclosure. FIG. 5A illustrates a wafer substrate 105 having a metallization stack 116 at a top surface (e.g., facing up) subsequent to performing an etching process from the top surface of the metallization stack 116 to create tapered sidewalls in the metallization stack 116 (e.g., the assembly of FIG. 4B). The etching process may include any suitable etching process. In some embodiments, a saw dicing process may be used. FIG. 5B illustrates an assembly subsequent to attaching a carrier 501 to a top surface of the assembly of FIG. 5A. A carrier 501 may include any suitable material for providing mechanical stability during manufacturing operations, and in some embodiments, may include a semiconductor wafer (e.g., a silicon wafer) or glass (e.g., a glass panel). FIG. 5C illustrates an assembly subsequent to performing a plasma dicing process from the bottom surface of the assembly of FIG. 5B to create tapered sidewalls in the wafer substrate 105. The assembly of FIG. 5C may undergo further processing, such as removing the carrier 501.

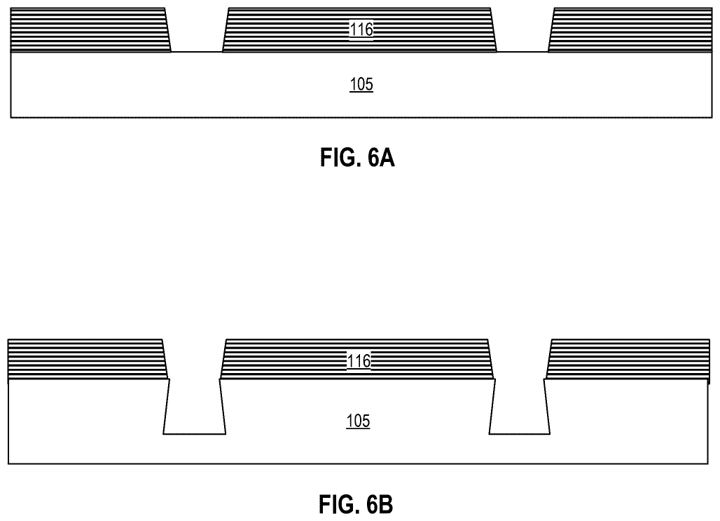

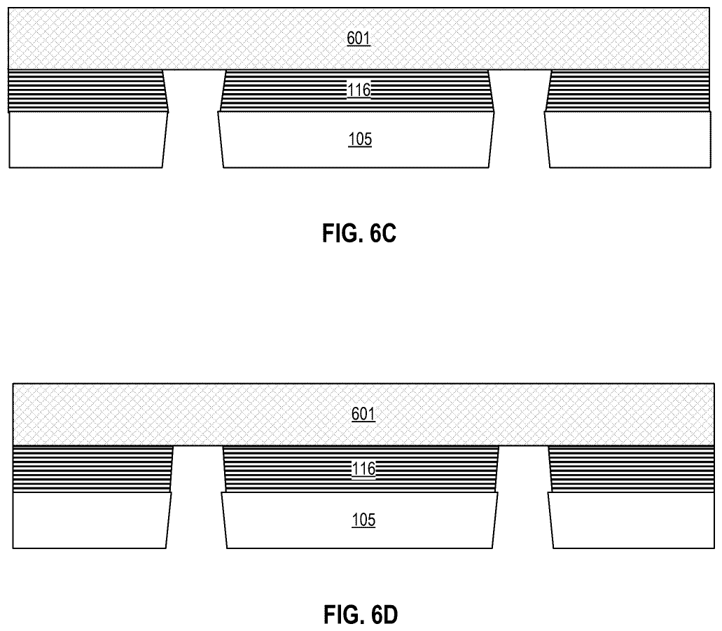

FIGS. 6A-6D are schematic cross-sectional views of different stages of an example process for manufacturing microelectronic assembly of FIG. 2A according to some embodiments of the present disclosure. FIG. 6A illustrates a wafer substrate 105 having a metallization stack 116 at a top surface (e.g., facing up) subsequent to performing an etching process from the top surface of the metallization stack 116 to create tapered sidewalls in the metallization stack 116 (e.g., the assembly of FIG. 4B). The etching process may include any suitable etching process. In some embodiments, a saw dicing process may be used. FIG. 6B illustrates an assembly subsequent to performing a plasma dicing process from the top surface of the assembly of FIG. 6A to create tapered sidewalls in the wafer substrate 105. The plasma dicing process may include an adjusted recipe to exaggerate the inverse taper in the wafer substrate 105. FIG. 6C illustrates an assembly subsequent to attaching a carrier 601 to a top surface of the assembly of FIG. 6B and performing a thinning process on a bottom surface of the assembly of FIG. 6B. A carrier 601 may include any suitable material for providing mechanical stability during manufacturing operations, and in some embodiments, may include a semiconductor wafer (e.g., a silicon wafer) or glass (e.g., a glass panel). The thinning process may include any suitable thinning process, such as CMP. FIG. 6D illustrates an assembly subsequent to performing a plasma dicing process from the bottom surface of the assembly of FIG. 6C to create tapered sidewalls in the wafer substrate 105. The assembly of FIG. 6D may undergo further processing, such as removing the carrier 601.

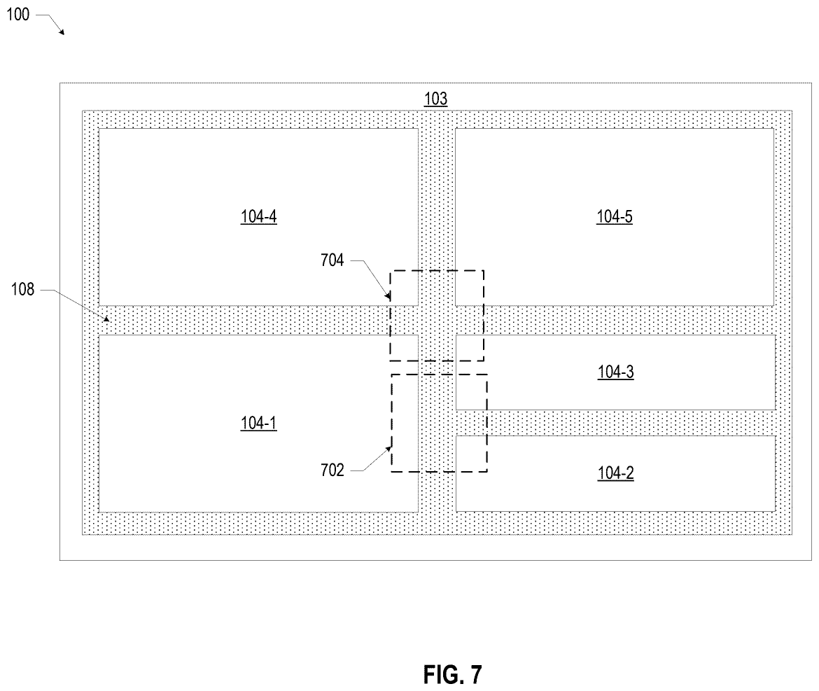

FIG. 7 is a schematic top view of an example arrangement of multi-die stacks in a microelectronic assembly according to some embodiments of the present disclosure. FIG. 7 illustrates a plurality of multi-die stacks 104 (e.g., 104-1, 104-2, 104-3, 104-4, 104-5) electrically coupled to a base die 103. The plurality of multi-die stacks 104 are arranged to include a T-shaped space 702 between multi-die stacks 104-1, 104-2, and 104-3, and a cross-shaped space 704 between multi-die stacks 104-1, 104-3, 104-4, and 104-5, where a dielectric material 108 surrounds the multi-die stacks 104 and fills the spaces 702, 704. The T-shaped space 702 (e.g., a 3-way intersection) may fill faster and may require less dielectric material as compared to the cross-shaped space 704 (e.g., a 4-way intersection). For example, a T-shaped space 702 may fill after depositing a thickness of 55 microns of dielectric material 108 while the cross-shaped space 704 may not be filled. Arranging a plurality of multi-die stacks 104 to optimize a number of T-shaped spaces 702 over cross-shaped spaces 704 may further reduce an amount of dielectric material 108 needed in a microelectronic assembly 100.

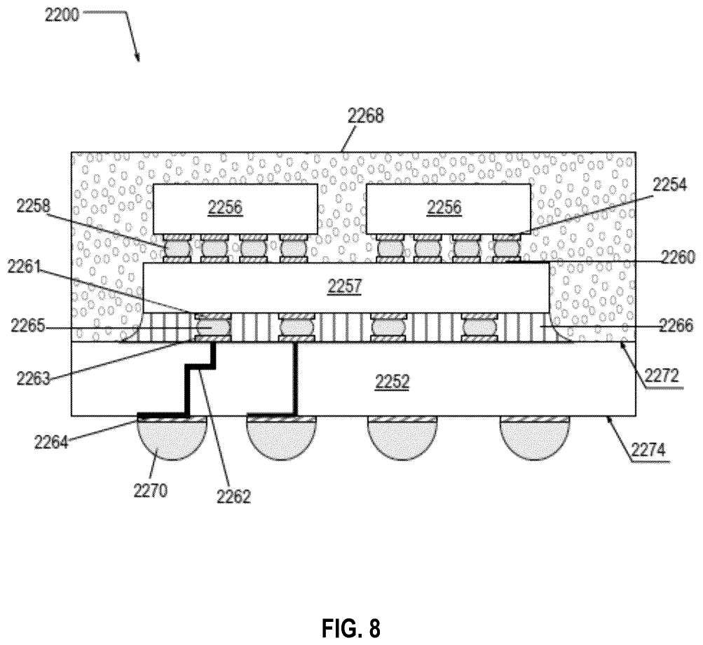

The packages disclosed herein, e.g., any of the microelectronic assemblies 100 or any further embodiments described herein, may be included in any suitable electronic component. FIGS. 8-10 illustrate various examples of packages, assemblies, and devices that may be used with or include any of the IC packages as disclosed herein.

FIG. 8 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

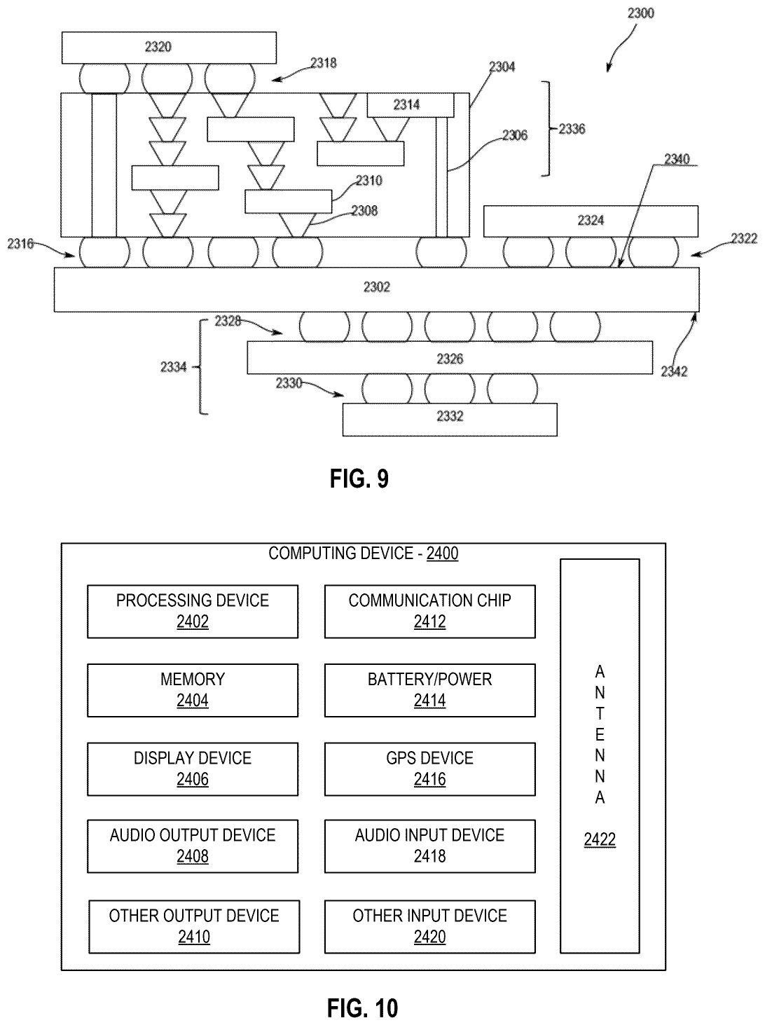

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 9.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 9 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 8.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 8. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 10 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 8). In yet another example, any one or more of the components of computing device 2400 may include an IC device assembly 2300 (e.g., as shown in FIG. 9).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SoC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

Example 1 is a microelectronic assembly, including a die; a first multi-die stack coupled to the die, wherein the first multi-die stack includes a plurality of dies having a first tapered profile with an internal angle between 77 degrees and 87 degrees; and a second multi-die stack coupled to the die adjacent to the first multi-die stack, wherein the second multi-die stack includes a plurality of dies having a second tapered profile with an internal angle between 77 degrees and 87 degrees, and wherein the first tapered profile and the second tapered profile form a space between the first multi-die stack and the second multi-die stack that narrows towards the die.

Example 2 may include the subject matter of Example 1, and may further include a dielectric material surrounding the first multi-die stack and the second multi-die stack, and in the space between the first multi-die stack and the second multi-die stack.

Example 3 may include the subject matter of Example 2, and may further specify that the dielectric material includes silicon and oxygen, or silicon, oxygen, and one or more of nitrogen and carbon.

Example 4 may include the subject matter of any of Examples 1-3, and may further specify that a thickness of the first multi-die stack is between 100 microns and 200 microns.

Example 5 may include the subject matter of any of Examples 1-4, and may further specify that a thickness of the second multi-die stack is between 100 microns and 200 microns.

Example 6 may include the subject matter of any of Examples 1-5, and may further specify that the first multi-die stack and the second multi-die stack have between 2 and 4 dies.

Example 7 may include the subject matter of any of Examples 1-6, and may further specify that the space between the first multi-die stack and the second multi-die stack has an aspect ratio equal to or greater than 0.4.

Example 8 may include the subject matter of any of Examples 1-7, and may further specify that the first multi-die stack and the second multi-die stack are electrically coupled to the die by interconnects having a pitch of less than 10 microns.

Example 9 may include the subject matter of any of Examples 1-8, and may further specify that the die includes a base die, an interposer, or a wafer.

Example 10 may include the subject matter of any of Examples 1-9, and may further specify that the die includes conductive pathways, and the microelectronic assembly may further include a through-dielectric via (TDV) in the space between the first multi-die stack and the second multi-die stack and electrically coupled to the die.

Example 11 may include the subject matter of any of Examples 1-10, and may further include a third multi-die stack coupled to the die adjacent to the first multi-die stack and the second multi-die stack, wherein the third multi-die stack includes a plurality of dies having a third tapered profile with an internal angle between 77 degrees and 87 degrees, and wherein a side of the third multi-die stack spans the space between the first multi-die stack and the second multi-die stack forming a T-shaped space that narrows towards the die.

Example 12 may include the subject matter of Example 11, and may further specify that the first multi-die stack is one of a plurality of first multi-die stacks, the second multi-die stack is one of a plurality of second multi-die stacks, and the third multi-die stack is one of a plurality of third multi-die stacks.

Example 13 is a microelectronic assembly, including a die; a first multi-die stack coupled to the die, wherein the first multi-die stack includes a plurality of dies having decreasing surface areas towards a top of the first multi-die stack forming a first tapered profile; a second multi-die stack coupled to the die adjacent to the first multi-die stack, wherein the second multi-die stack includes a plurality of dies having decreasing surface areas towards a top of the second multi-die stack forming a second tapered profile, and wherein the first tapered profile and the second tapered profile form a space between the first multi-die stack and the second multi-die stack that narrows towards the die; and a dielectric material surrounding the first multi-die stack and the second multi-die stack, and in the space between the first multi-die stack and the second multi-die stack.

Example 14 may include the subject matter of Example 13, and may further specify that the first tapered profile and the second tapered profile have an internal angle between 77 degrees and 87 degrees.

Example 15 may include the subject matter of Example 13 or 14, and may further specify that the dielectric material includes silicon and oxygen, or silicon, oxygen, and one or more of nitrogen and carbon.

Example 16 may include the subject matter of any of Examples 13-15, and may further specify that a thickness of the first multi-die stack is between 100 microns and 200 microns.

Example 17 may include the subject matter of any of Examples 13-16, and may further specify that a thickness of the second multi-die stack is between 100 microns and 200 microns.

Example 18 may include the subject matter of any of Examples 13-17, and may further specify that the first multi-die stack and the second multi-die stack have between 2 and 4 dies.

Example 19 may include the subject matter of any of Examples 13-18, and may further specify that the space between the first multi-die stack and the second multi-die stack has an aspect ratio equal to or greater than 0.4.

Example 20 may include the subject matter of any of Examples 13-19, and may further specify that the first multi-die stack and the second multi-die stack are electrically coupled to the die by interconnects having a pitch of less than 10 microns.

Example 21 may include the subject matter of any of Examples 13-20, and may further specify that the die includes a base die, an interposer, or a wafer.

Example 22 may include the subject matter of any of Examples 13-21, and may further specify that the die includes conductive pathways, and the microelectronic assembly may further include a through-dielectric via (TDV) in the space between the first multi-die stack and the second multi-die stack and electrically coupled to the die.

Example 23 may include the subject matter of any of Examples 13-22, and may further include a third multi-die stack coupled to the die adjacent to the first multi-die stack and the second multi-die stack, wherein the third multi-die stack includes a plurality of dies having decreasing surface areas towards a top of the third multi-die stack forming a third tapered profile, and wherein a side of the third multi-die stack spans the space between the first multi-die stack and the second multi-die stack forming a T-shaped space that narrows towards the die.

Example 24 may include the subject matter of Example 23, and may further specify that the first multi-die stack is one of a plurality of first multi-die stacks, the second multi-die stack is one of a plurality of second multi-die stacks, and the third multi-die stack is one of a plurality of third multi-die stacks.

Example 25 is a microelectronic assembly, including a die; a first multi-die stack coupled to the die, wherein the first multi-die stack includes a plurality of dies surrounded by a first dielectric material having a first tapered profile with an internal angle between 77 degrees and 87 degrees; and a second multi-die stack coupled to the die adjacent to the first multi-die stack, wherein the second multi-die stack includes a plurality of dies surrounded by a second dielectric material having a second tapered profile with an internal angle between 77 degrees and 87 degrees, and wherein the first tapered profile and the second tapered profile form a space between the first multi-die stack and the second multi-die stack that narrows towards the die.

Example 26 may include the subject matter of Example 25, and may further specify that the first dielectric material and the second dielectric material include silicon and oxygen, or silicon, oxygen, and one or more of nitrogen and carbon.

Example 27 may include the subject matter of Example 25 or 26, and may further specify that a thickness of the first multi-die stack is between 100 microns and 200 microns.

Example 28 may include the subject matter of any of Examples 25-27, and may further specify that a thickness of the second multi-die stack is between 100 microns and 200 microns.

Example 29 may include the subject matter of any of Examples 25-28, and may further specify that the first multi-die stack and the second multi-die stack have between 2 and 4 dies.

Example 30 may include the subject matter of any of Examples 25-29, and may further specify that the space between the first multi-die stack and the second multi-die stack has an aspect ratio equal to or greater than 0.4.

Example 31 may include the subject matter of any of Examples 25-30, and may further specify that the first multi-die stack and the second multi-die stack are electrically coupled to the die by interconnects having a pitch of less than 10 microns.

Example 32 may include the subject matter of any of Examples 25-31, and may further specify that the die includes a base die, an interposer, or a wafer.

Example 33 may include the subject matter of any of Examples 25-32, and may further specify that the die includes conductive pathways, and the microelectronic assembly may further include a through-dielectric via (TDV) in the space between the first multi-die stack and the second multi-die stack and electrically coupled to the die.

Example 34 may include the subject matter of any of Examples 25-33, and may further include a third multi-die stack coupled to the die adjacent to the first multi-die stack and the second multi-die stack, wherein the third multi-die stack includes a plurality of dies surrounded by a third dielectric material having a third tapered profile with an internal angle between 77 degrees and 87 degrees, and wherein a side of the third multi-die stack spans the space between the first multi-die stack and the second multi-die stack forming a T-shaped space that narrows towards the die.

Example 35 may include the subject matter of Example 34, and may further specify that the first multi-die stack is one of a plurality of first multi-die stacks, the second multi-die stack is one of a plurality of second multi-die stacks, and the third multi-die stack is one of a plurality of third multi-die stacks.

1. A microelectronic assembly, comprising:
a die;
a first multi-die stack coupled to the die, wherein the first multi-die stack includes a plurality of dies having a first tapered profile with an internal angle between 77 degrees and 87 degrees; and
a second multi-die stack coupled to the die adjacent to the first multi-die stack, wherein the second multi-die stack includes a plurality of dies having a second tapered profile with an internal angle between 77 degrees and 87 degrees, and wherein the first tapered profile and the second tapered profile form a space between the first multi-die stack and the second multi-die stack that narrows towards the die.

2. The microelectronic assembly of claim 1, further comprising:
a dielectric material surrounding the first multi-die stack and the second multi-die stack, and in the space between the first multi-die stack and the second multi-die stack.

3. The microelectronic assembly of claim 2, wherein the dielectric material includes silicon and oxygen, or silicon, oxygen, and one or more of nitrogen and carbon.

4. The microelectronic assembly of claim 1, wherein a thickness of the first multi-die stack is between 100 microns and 200 microns.

5. The microelectronic assembly of claim 1, wherein a thickness of the second multi-die stack is between 100 microns and 200 microns.

6. The microelectronic assembly of claim 1, wherein the first multi-die stack and the second multi-die stack have between 2 and 6 dies.

7. The microelectronic assembly of claim 1, wherein the first multi-die stack and the second multi-die stack are electrically coupled to the die by interconnects having a pitch of less than 10 microns.

8. The microelectronic assembly of claim 1, wherein the die includes a base die, an interposer, or a wafer.

9. The microelectronic assembly of claim 1, further comprising:
a third multi-die stack coupled to the die adjacent to the first multi-die stack and the second multi-die stack, wherein the third multi-die stack includes a plurality of dies having a third tapered profile with an internal angle between 77 degrees and 87 degrees, and wherein a side of the third multi-die stack spans the space between the first multi-die stack and the second multi-die stack forming a T-shaped space that narrows towards the die.

10. The microelectronic assembly of claim 1, wherein the die includes conductive pathways and microelectronic assembly further comprising:
a through-dielectric via (TDV) in the space between the first multi-die stack and the second multi-die stack and electrically coupled to the die.

11. A microelectronic assembly, comprising:
a die;
a first multi-die stack coupled to the die, wherein the first multi-die stack includes a plurality of dies having decreasing surface areas towards a top of the first multi-die stack forming a first tapered profile;
a second multi-die stack coupled to the die adjacent to the first multi-die stack, wherein the second multi-die stack includes a plurality of dies having decreasing surface areas towards a top of the second multi-die stack forming a second tapered profile, and wherein the first tapered profile and the second tapered profile form a space between the first multi-die stack and the second multi-die stack that narrows towards the die; and
a dielectric material surrounding the first multi-die stack and the second multi-die stack, and in the space between the first multi-die stack and the second multi-die stack.

12. The microelectronic assembly of claim 11, wherein the first tapered profile and the second tapered profile have an internal angle between 77 degrees and 87 degrees.

13. The microelectronic assembly of claim 11, wherein the dielectric material includes silicon and oxygen, or silicon, oxygen, and one or more of nitrogen and carbon.

14. The microelectronic assembly of claim 11, further comprising:
a third multi-die stack coupled to the die adjacent to the first multi-die stack and the second multi-die stack, wherein the third multi-die stack includes a plurality of dies having decreasing surface areas towards a top of the third multi-die stack forming a third tapered profile, and wherein a side of the third multi-die stack spans the space between the first multi-die stack and the second multi-die stack forming a T-shaped space that narrows towards the die.

15. The microelectronic assembly of claim 14, wherein the first multi-die stack is one of a plurality of first multi-die stacks, the second multi-die stack is one of a plurality of second multi-die stacks, and the third multi-die stack is one of a plurality of third multi-die stacks.

16. A microelectronic assembly, comprising:
a die;
a first multi-die stack coupled to the die, wherein the first multi-die stack includes a plurality of dies surrounded by a first dielectric material having a first tapered profile with an internal angle between 77 degrees and 87 degrees; and
a second multi-die stack coupled to the die adjacent to the first multi-die stack, wherein the second multi-die stack includes a plurality of dies surrounded by a second dielectric material having a second tapered profile with an internal angle between 77 degrees and 87 degrees, and wherein the first tapered profile and the second tapered profile form a space between the first multi-die stack and the second multi-die stack that narrows towards the die.

17. The microelectronic assembly of claim 16, wherein the first dielectric material and the second dielectric material include silicon and oxygen, or silicon, oxygen, and one or more of nitrogen and carbon.

18. The microelectronic assembly of claim 16, wherein a thickness of the first multi-die stack is between 100 microns and 200 microns.

19. The microelectronic assembly of claim 16, wherein a thickness of the second multi-die stack is between 100 microns and 200 microns.

20. The microelectronic assembly of claim 16, further comprising:
a third multi-die stack coupled to the die adjacent to the first multi-die stack and the second multi-die stack, wherein the third multi-die stack includes a plurality of dies surrounded by a third dielectric material having a third tapered profile with an internal angle between 77 degrees and 87 degrees, and wherein a side of the third multi-die stack spans the space between the first multi-die stack and the second multi-die stack forming a T-shaped space that narrows towards the die.
